(19) United States
(12) Patent Application Publication
(10) Pub. No.: US 2012/0229162 A1
(43) Pub. Date: Sep. 13, 2012

(54) Non-Contact Testing Devices for Printed Circuit Boards Transporting High-Speed Signals

(75) Inventor: Alexandre Guterman, Ottawa (CA)

(73) Assignee: TELEFONAKTIEBOLAGET L M ERICSSON (PUBL), Stockholm (SE)

(21) Appl. No.: 13/041,937

(22) Filed: Mar. 7, 2011

(51) Int. Cl. G01R 31/304

(52) U.S. Cl. 324/763.01

(57) ABSTRACT

Non-contact testing devices formed on a printed circuit board (PCB), to enable testing high-speed signals propagating along at least one signal track located on a signal layer of the PCB, and methods of testing high-speed signals using thereof are provided. A non-contact testing device includes a non-contact testing track formed on a layer of the PCB, and having at least one portion substantially parallel with the at least one signal track and a testing point located at an end of the non-contact testing track.

### TECHNICAL FIELD

The present invention generally relates to devices and methods used for testing high-speed signals on printed circuit boards, and, in particular, to using the crosstalk effect for a non-contact testing technique.

### BACKGROUND

Worldwide development of communication gears towards higher and higher speed signals. The term “high-speed” may be considered as characterizing the data rate or alternatively the slew rate. Since the digital signals have two states “0” and “1”, the transmission speed is limited by a circuit capacity to preserve voltage levels and waveforms to a degree which enables accurately recognizing the state in each time interval (a duration of which decreases with the increase of the data rate), thus, achieving a low bit-error rate. Relative to the data rate, currently digital signals having data rates over 100 Mbps are considered to be high-speed signals but, as technology develops, the term “high” may become associated to higher data rates than 100 Mbps. The technological progress allows higher and higher the data rates while keeping the bit error rates at low/acceptable level.

The slew rate represents the maximum rate of change of a signal at any point in a circuit. The slew rate reflects even more directly the quality of the underlying hardware to maintain the signal integrity, because it relates to the degrading of the signal shape during transmission (which shape may be different from the rectangular shape of the digital signals). The term “high-speed signal(s)” as used hereinafter covers both meanings, standing for high data rate and/or high slew rate signals.

Printed circuit boards (PCBs) used in transporting and processing high-speed signals are monitored for signal integrity and tested for compliance to standards and for detection and location of stuck-at and transient or soft fault, using off-line and/or in-circuit testing techniques. Conventionally, test points are connected directly to electrical nodes to probe and measure the signals on the PCBs. A conventional contact testing point comprises an interconnect track and a test pad or via, and is further connected to probing circuitry from an automatic testing equipment (ATE), from a measurement instrument or from an in-circuit testing device. The conventional testing point components and the probing circuitry are loads that affect the signal during probing and testing. These loads disturb the measured signals and therefore the results of these measurements do not reflect the normal operation conditions.

A schematic diagram on a conventional contact testing device is illustrated in FIG. 1, where the interconnect track lines 20 and 22 are connected to the signal lines 10 and 12 through which signal propagates from a driver 30 to a receiver 40. The conventional contact testing device, which includes test pads, interconnect track lines 20 and 22 and a test signal receiver 25, has a capacitance of 1-10 pF. The high-speed signal output by the driver 30, which is illustrated in graph 50 of voltage versus time in FIG. 2, suffers a slew degradation, a deterministic jitter, and eye closure as illustrated in graph 60 of voltage versus time diagram of FIG. 2, due to the presence of the conventional contact testing device. Therefore, a higher bit error rate (BER) occurs during a measurement than during a normal operation (when the conventional contact testing device is not attached).

Crosstalk is a phenomenon occurring in electronic circuit by which a signal transmitted on one circuit or channel creates an echo in another circuit or channel. In PCB design, this phenomenon is viewed as undesirable and various techniques are employed to minimize its impact on the intended signals. However, sometimes the phenomenon may be employed for achieving desirable outcomes. For example, U.S. Pat. No. 6,016,086 (incorporated herewith by reference) discloses a bus for high signal quality interconnections, comprising non-contact couplers terminated by different impedances, for producing at least one common mode reflection, under-damping the signal and/or reducing the common mode noise. These non-contact couplers cause the reflections from vias, connectors and other like impedance discontinuities to be re-reflected in common mode so that they are rejected by a differential receiver. In another example, described in the paper “Point-to-multipoint Gigabit Backplane Design” by Guterman, A. and Zani, R. (which paper was published in Electromagnetic Compatibility, 2003. EMC '03. 2003, vol. 2, 1106-1109, ISBN: 0-7803-7779-6 and is incorporated herewith by reference) a contactless midplane is used to enhance backplane performance.

Nowadays, due to increasing data-rates and higher quality requirements, additional loads and alteration of the tested signals occurring when using conventional contact test points cannot be tolerated, being detrimental to signal integrity and performance.

Accordingly, it would be desirable to develop new techniques and devices usable off-line or performing in-circuit testing, to monitor signal integrity, determine compliance to standards and/or detection/location of stuck-at and transient/soft faults, which new techniques to avoid the afore-described problems and drawbacks.

### SUMMARY

Non-contact testing devices according to various embodiments have less impact on the tested signals than the conventional contact testing points. Some of the design parameters that can be tuned to optimize testing for different situations evidence particular advantages.

According to one exemplary embodiment, a method of testing high-speed signals propagating along at least one signal track on a signal layer of a printed circuit board (PCB) is provided. The method includes forming a non-contact testing track on a layer of the PCB, the non-contact testing track having at least one portion substantially parallel with the at least one signal track. The method further includes connecting a testing point to an end of the non-contact testing track to enable measuring a crosstalk signal corresponding to the tested signal.

According to another exemplary embodiment, a method of testing high-speed signals propagating along at least one signal track on a signal layer of a printed circuit board (PCB) is provided. The method includes carving a moat in a reference layer of the PCB adjacent to the signal layer, to form a non-contact testing track having at least one portion substantially parallel with the at least one signal track. The method further includes connecting a testing point to an end of the non-contact testing track away from a non-carved surface of the reference layer, to enable measuring a crosstalk signal corresponding to the tested signal.

According to another exemplary embodiment, a non-contact testing device formed on a printed circuit board (PCB), to enable testing high-speed signals propagating along at least one signal track located on a signal layer of the PCB includes a non-contact testing track and a testing point. The non-contact testing track is formed on a layer of the PCB, and has at least one portion substantially parallel with the at least one signal track. The testing point is located on an end of the non-contact testing track.

According to another embodiment, a non-contact testing device formed on a printed circuit board (PCB), to enable testing high-speed signals propagating along at least one signal track located on a signal layer of the PCB includes a non-contact testing track and a testing point. The non-contact testing track is formed by etching a moat on a reference layer of the PCB, the reference layer being adjacent to the signal layer, and the non-contact testing track having at least one portion substantially parallel with the at least one signal track. The testing point is located at an end of the non-contact testing track away from a non-carved surface of the reference layer.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 is a schematic diagram of a conventional contact testing device;

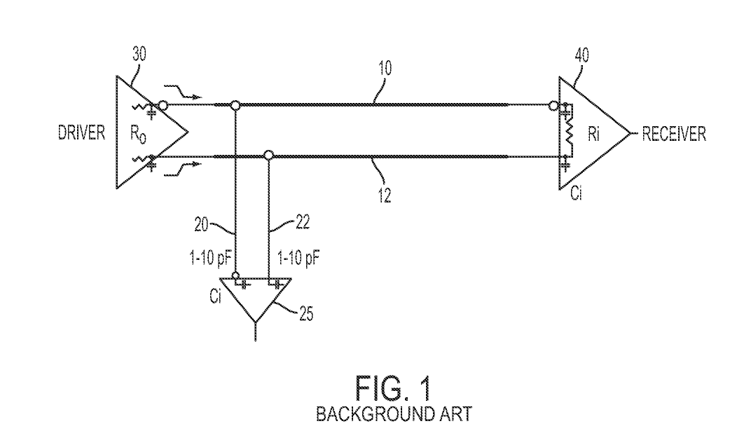

FIG. 2 is a graph illustrating a voltage versus time for a high-speed signal without a conventional contact testing device and with a conventional contact testing device;

FIG. 3A is a flow diagram of a method of testing high-speed signals propagating along at least one signal track on a signal layer of a printed circuit board according to an exemplary embodiment;

FIG. 3B is a flow diagram of a method of testing high-speed signals propagating along at least one signal track on a signal layer of a printed circuit board according to another exemplary embodiment;

FIG. 4 is a schematic diagram of a non-contact testing point according to an exemplary embodiment;

FIG. 5 is a graph illustrating a voltage versus time for a high-speed signal without a non-contact testing point and with a non-contact testing point according to an exemplary embodiment;

FIGS. 6A and 6B illustrates location along signal lines of non-contact testing tracks for different topologies of the signal lines, according to exemplary embodiments;

FIGS. 7A and 7B illustrate evolution for a crosstalk signal corresponding to a saturation crosstalk regime and to a non-saturation crosstalk regime respectively, according to exemplary embodiments;

FIG. 8 is a graph illustrating evolution of crosstalk signals corresponding to high-speed signals for the saturation crosstalk regime, the non-saturation crosstalk regime and on the verge of passing from the non-saturation crosstalk regime to the saturation crosstalk regime, according to exemplary embodiments;

FIG. 9 is a graph illustrating the effect of the data rates on the amplitude of the crosstalk signal, according to an exemplary embodiment;

FIG. 10 is a graph illustrating the effect of capacitive loads corresponding to different coupler lengths, on the amplitude of the crosstalk signal, according to an exemplary embodiment;

FIG. 11 illustrates exemplary embodiments of non-contact testing devices located on signal layers of a PCB;

FIG. 12 is a graph illustrating the effect of the separation between the signal track and the track of the non-contact testing device, on the amplitude of the crosstalk signal, according to an exemplary embodiment;

FIG. 13 illustrates a plane view of a non-contact testing device formed on a reference plane, according to an exemplary embodiment;

FIG. 14 illustrates exemplary embodiments of non-contact testing devices located on reference layers of the PCB;

FIG. 15 illustrates a plane view of a non-contact testing device formed on a reference plane, according to another exemplary embodiment;

FIG. 16 illustrates a PCB sectional view of a non-contact testing device formed on a shadow ground plane according to an exemplary embodiment;

FIG. 17 is a graph illustrating the effect of different manners of terminating the non-contact testing tracks on the crosstalk signals, according to exemplary embodiments;

FIG. 18 is a graph illustrating the effect of different manners of forming non-contact testing tracks on the crosstalk signals terminated directly to ground, according to exemplary embodiments;

FIG. 19 is a schematic diagram of a complementary non-contact testing device according to an embodiment;

FIG. 20 illustrates simulations of a signal reaching a receiver and of a corresponding crosstalk signal acquired by a non-contact testing device located close to the receiver, according to an exemplary embodiment; and

FIG. 21 illustrates simulations of a signal output by a driver and of a corresponding crosstalk signal acquired by a non-contact testing device located close to the driver, according to an exemplary embodiment.

### DETAILED DESCRIPTION

The following description of the exemplary embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to the terminology and structure of printed circuit boards used for transmitting high-speed signals. However, the embodiments to be discussed next are not limited to these systems but may be applied to other existing electronics hardware used in transmitting signals.

Reference throughout the specification to “one embodiment” or “an embodiment” means that a particular feature, structure, or characteristic described in connection with an embodiment is included in at least one embodiment of the present invention. Thus, the appearance of the phrases “in one embodiment” or “in an embodiment” in various places throughout the specification is not necessarily all referring to the same embodiment. Further, the particular features, structures or characteristics may be combined in any suitable manner in one or more embodiments.

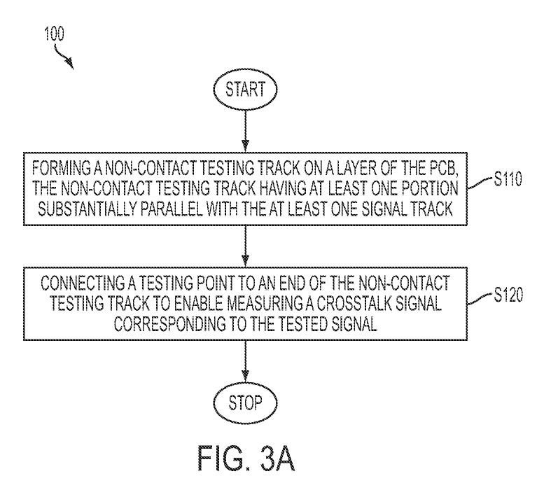

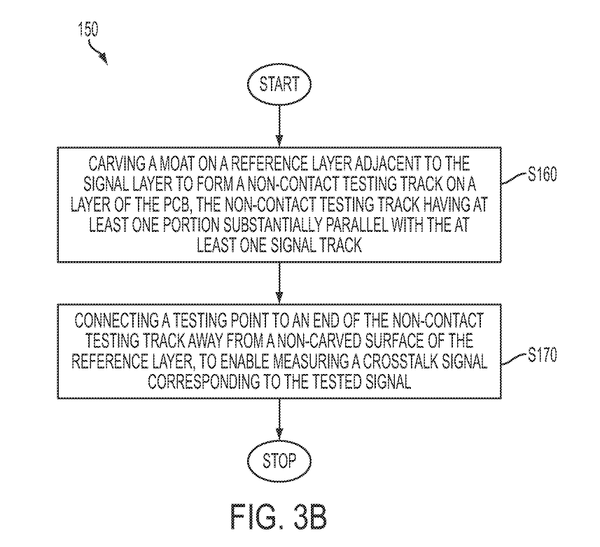

A flow diagram of method 100 of testing high-speed signals transmitted along a track on a signal layer of a printed circuit board (PCB), according to an exemplary embodiment, is illustrated in FIG. 3A. The method 100 includes forming a non-contact testing track on a layer of the PCB, at S110. The non-contact testing track has at least one portion substantially parallel with the signal track. The term “substantially parallel” used here includes the situation in which the non-contact testing track is formed on another layer than the signal layer. Further, at S120, the method 100 includes connecting a testing point to an end of the non-contact testing track to enable measuring a cross-talk signal corresponding to the tested signal.

A flow diagram of method 150 of testing high-speed signals transmitted along a track on a signal layer of a printed circuit board (PCB), according to another exemplary embodiment, is illustrated in FIG. 3B. The method 150 includes carving a moat on a reference layer adjacent to the signal layer to form a non-contact testing track, at S160. The non-contact testing track has at least one portion substantially parallel with the signal track. Further, at S170, the method 150 includes connecting a testing point to an end of the non-contact testing track away from a non-carved surface of the reference layer, to enable measuring a cross-talk signal corresponding to the tested signal.

When a signal (e.g., a digital signal) is transmitted along an interconnect track the crosstalk phenomenon occurs and an echo signal is produced in the portion of the non-contact testing track which is substantially parallel with the signal track.

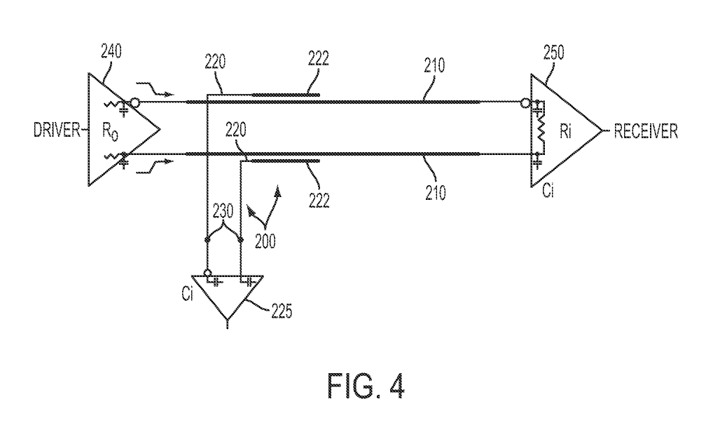

FIG. 4 is a schematic diagram of a non-contact testing point setup. Although high-speed signals may be transmitted using a single line, the differential lines carrying complementary signals are more frequently used due to their advantages (e.g., tolerance to ground offsets, suitability for usage with low voltage electronics, resistance to interferences, etc.). The setup of FIG. 4 illustrates differential lines 210 along which a signal (e.g., a digital signal) propagates from a driver 240 to a receiver 250.

A non-contact testing device 200 includes non-contact testing tracks 220 having parallel portions 222 and ending at a testing point 230. Due to the crosstalk phenomenon, the signal passing through the differential lines 210 yields the echo signal in the parallel portions 222 of the non-contact testing tracks 220. Note that in principle, a single parallel track may also be used, but double tracks 222 are used to pick up complementary signals for the same reasons as using the differential lines instead of a single line. The echo signals occurring in the parallel portions 222 may be input to an amplifier 225. The non-contact testing tracks other than the parallel portions 222 and the amplifier 225 have a capacitance of 1-10 pF similar to the capacitance in the contact testing device case. The equivalent capacitance of the non-contact testing device 200 is that of a capacitor of 1-10 pF (corresponding to the connecting lines 220) in series with a capacitor of less than 0.1 pF due to the crosstalk coupling of the parallel portion. Thus, the equivalent capacitance of the non-contact testing device 200 is less than 0.1 pF resulting in a substantial lower load and signal degradation than the conventional contact testing device.

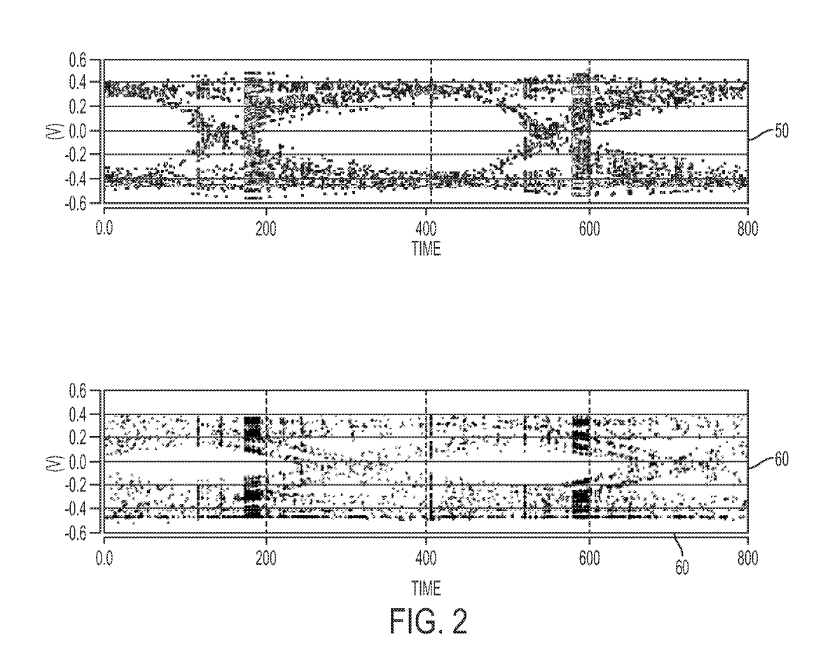

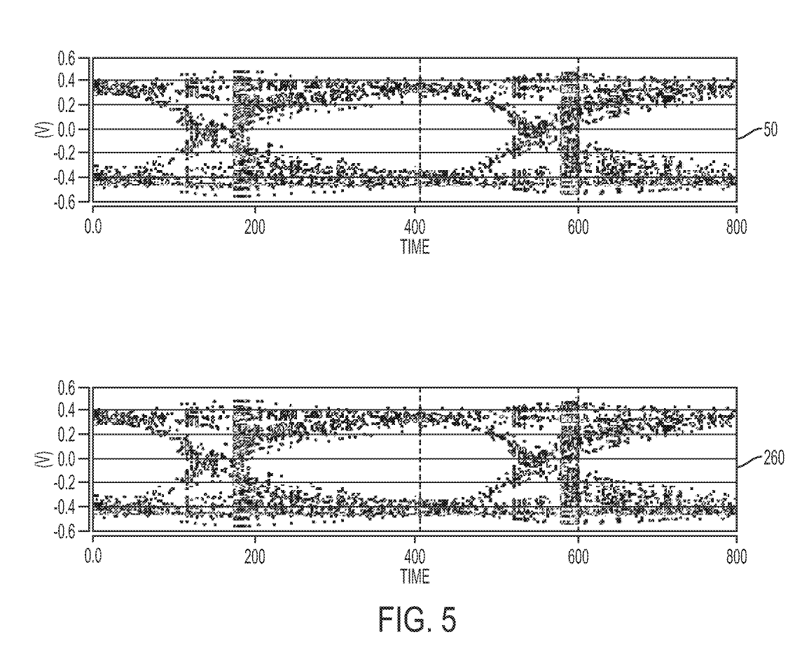

In the presence of the non-contact testing device 200, a high-speed signal output by the driver 240, which is illustrated in graph 50 of voltage versus time in FIG. 5 (the same as in FIG. 2), suffers less slew degradation, deterministic jitter, and eye closure, and, thus, has a lower BER as illustrated in graph 260, than in the presence of a conventional contact testing device as illustrated in graph 60 of FIG. 2.

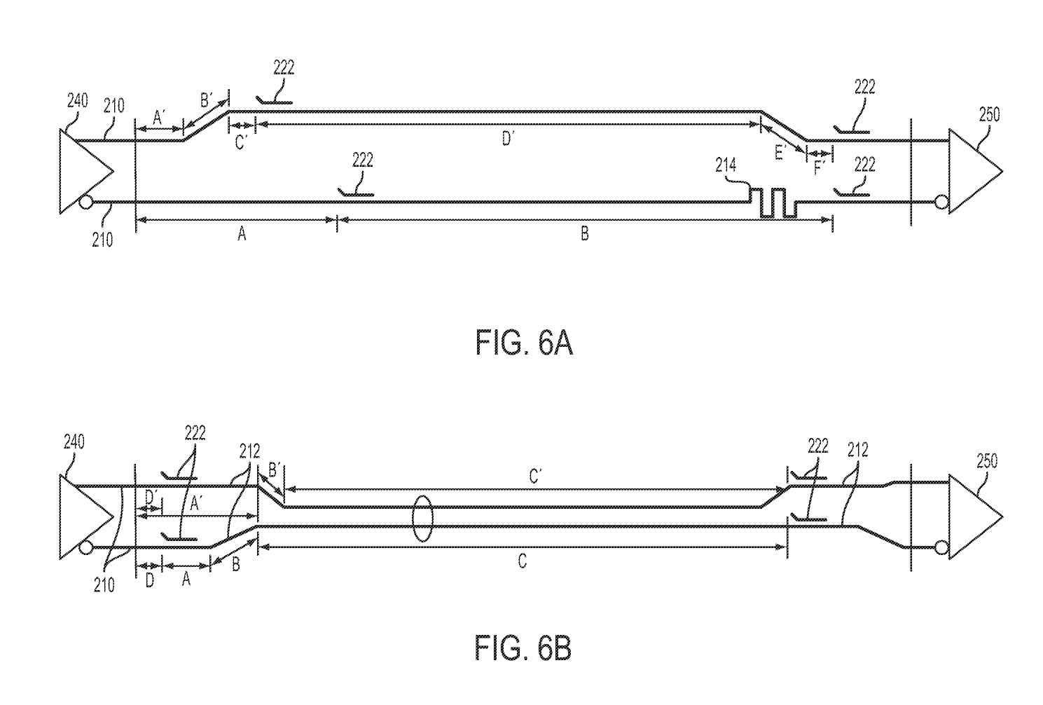

The schematic diagram in FIG. 4, illustrates the portions 222 as being positioned at the same ‘electrical’ distance from the driver 240 (or the receiver 250) and the distance between the differential lines 210 as being constant throughout the path between the driver 240 and the receiver 250. However, the reality of PCBs design is usually more complex and features of the lines along which signal is transmitted impact the manner in which the non-contact testing tracks are formed. For example, when the driver 240 and the receiver 250 are close to each other (i.e., a short distance there-between), the differential lines 210 are usually routed apart from each other as single ended lines, farther apart from each other as illustrated in FIG. 6A. On the other hand, when the driver 240 and the receiver 250 are farther apart, often the differential lines 210 are routed to be closer to each other using breakout tracks 212, to be tightly coupled as illustrated in FIG. 6B. In both cases, the total lengths of the two lines are matched, i.e., in FIG. 6B, A+B+C=A′+B′+C′, and, in FIG. 6A, A+B=A′+B′+C′+D′+E′+F′ (note here B includes a serpentine 214 included in portion B to achieve the same length). The pairs of parallel portions 222 (plural possible positions are illustrated) are placed at the same electrical length, preferably in areas where the coupling between the differential lines is smaller. Thus, in FIG. 6A, A′+B′+C′=A, and in FIG. 6B, D=D′.

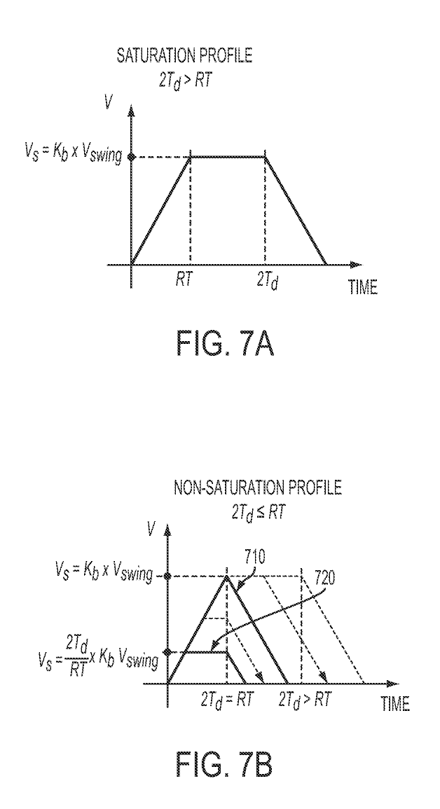

Depending on geometry, two types of crosstalk regime can occur when a non-contact testing device is used: (a) a saturation regime and (b) a non-saturation regime. Two time parameters interplay in determining the crosstalk regime: the flight-time and the rise-time. The flight-time (T_{d}) is the time of propagation of the signal from one end to the other of the parallel portion of the non-contact track. The rise-time (RT) is a time necessary for the signal to reach a maximum potential value after switching from a low to a high voltage. FIG. 7A illustrates evolution (i.e., the time is represented along the x-axis of the graph) of a voltage (represented on y-axis) acquired in the non-contact testing track for the saturation regime. Thus, if the rise-time is less than twice the flight-time (RT<2T_{d}), the signal reaches a maximum potential value Vₛ equal to a product of a coupling coefficient K_{b} between the signal line (e.g., 210) and the parallel portion (e.g., 222) of the non-contact track and a potential difference on the signal line when switching between states V_{swing} (i.e., Vₛ=K_{b}×V_{swing}). When the crosstalk regime is the saturation regime this maximum value is maintained for a while, before decreasing.

FIG. 7B illustrates evolution of voltage on the non-contact testing track in the non-saturation regime (when RT≧2Td). On the verge of the saturation 710, when RT=2T_{d}, the potential rises to the maximum value for the saturation regime (i.e., Vₛ=K_{b}×V_{swing}) and decreases immediately. If RT<2T_{d}, as illustrated by line 720, before decreasing, the potential rises to a value lower than the maximum value for the saturation regime Vₛ=2T_{d}/RT×K_{b}×V_{swing}.

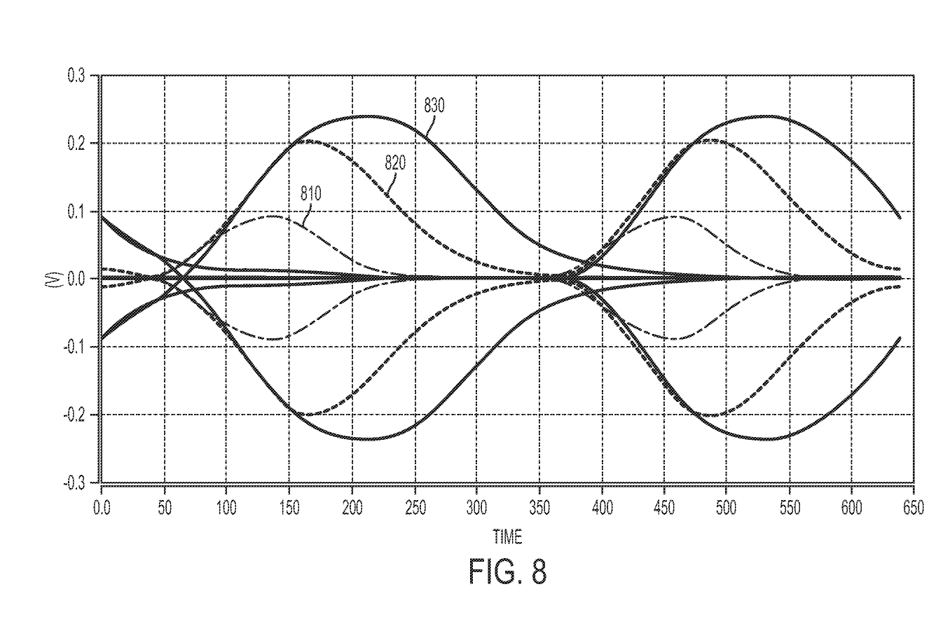

The saturation regime means a higher load on the system due to the presence of the non-contact testing device. On the other hand, one would prefer to take full advantage of the sensitivity of a measurement device and thus reaching the maximum potential value. Therefore, preferably, for an expected data rate, the length of the parallel portion of the testing track is selected such as the crosstalk signal to be on the verge of saturation, i.e., at a limit between the saturation regime and the non-saturation regime. FIG. 8 illustrates amplitude (potential) of signals acquired by a non-contact testing device as a function of time. Line 810 corresponds to the non-saturation regime, line 820 to the verge of saturation, and line 830 corresponds to the saturation regime.

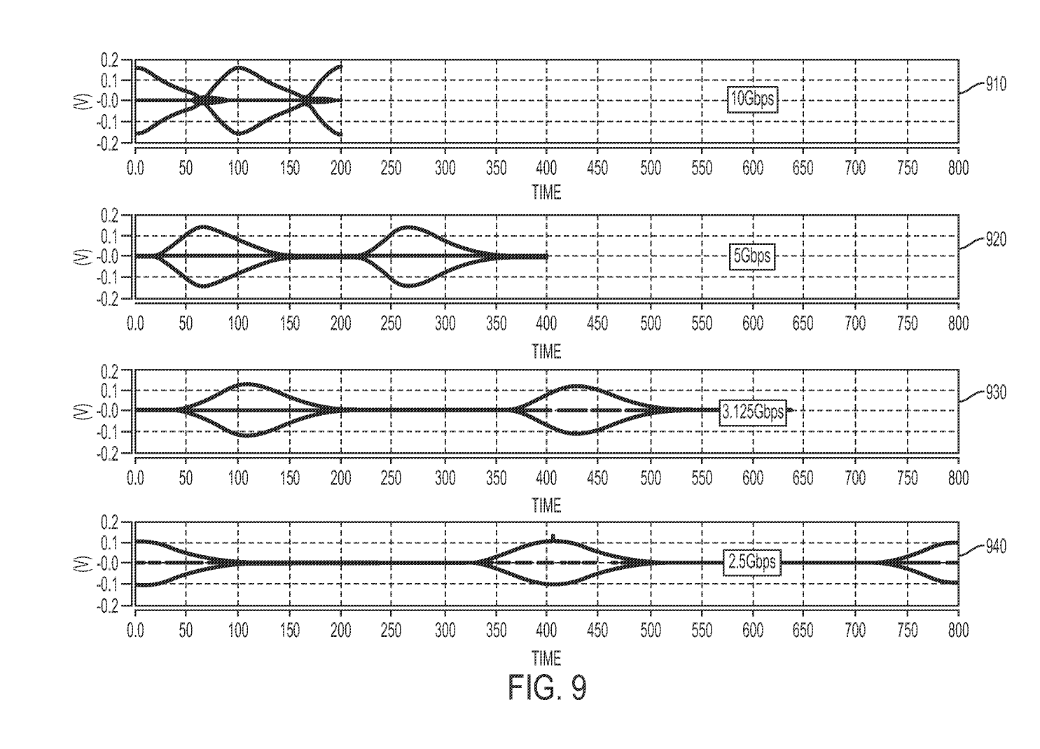

Once a non-contact testing track is formed on a PCB, the evolution of the signals acquired by a non-contact testing device depends also by the data rate of the data signal transmitted along the tested line. For example in FIG. 9, for the same non-contact testing device, the first graph 910, corresponds to a data rate of 10 Gbps, the second graph 920, corresponds to a data rate of 5 Gbps, the third graph 930, corresponds to a data rate of 3.125 Gbps, and the fourth graph 940, corresponds to a data rate of 2.5 Gbps.

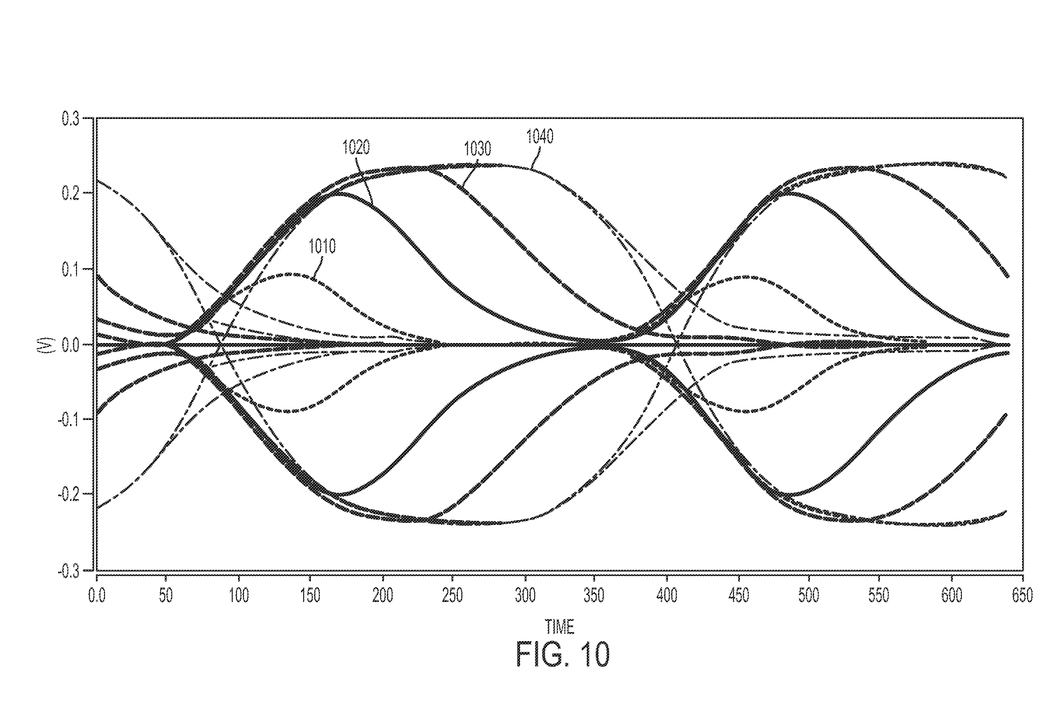

As illustrated in FIG. 10, there is a direct correlation between the length of the parallel portion of the non-contact track and its equivalent capacitance. Thus, line 1010 corresponds to a length of about 2.5 mm and a capacitance of less than 0.1 pF, line 1020 corresponds to a length of about 7.5 mm and a capacitance of about 0.2 pF, line 1030 corresponds to a length of about 12.5 mm and a capacitance of about 0.4 pF, and line 1040 corresponds to a length of about 17.5 mm and a capacitance of about 0.5 pF.

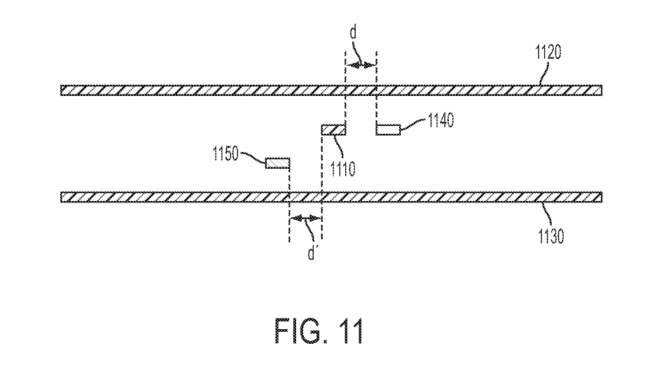

The non-contact track may be formed on the same (signal) layer as the signal line or formed on an adjacent (signal) layer of a multilayer PCB. For example, FIG. 11 illustrates a cross-section through layers of a PCB, in which a signal line 1110 is formed on a signal layer between two reference planes 1120 and 1130. A non-contact track may be formed on the signal layer as an edge-side coupler 1140 (at a distance d from the signal line 1110), or may be formed in another adjacent layer as a broadside/diagonal coupler 1150 (at a distance d′ from the signal line 1110).

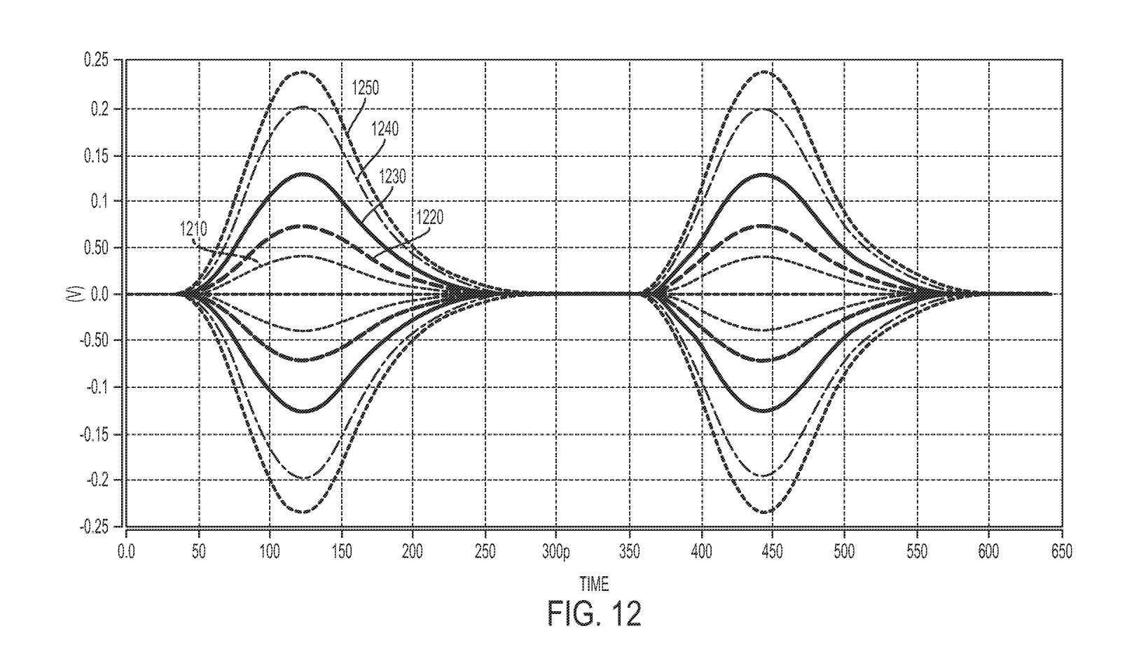

A maximum voltage of the crosstalk signal depends on the coupling coefficient K_{b}, which is proportional to a distance between the signal line and the parallel portion of the non-contact track. For the purpose of illustration and not of limitation, FIG. 12 illustrates amplitude of signals for testing track including a parallel portion (broadside/diagonal coupler) having a length of 5 mm and a width of 100 pm for a signal rate of 3.125 Gbps. Line 1210 corresponds to a distance (d′ in FIG. 11) between the signal line and the testing track of 300 μm, line 1220 corresponds to a side distance between the signal line and the parallel portion of the testing track of 200 μm, line 1230 corresponds to a distance between the signal line and the parallel portion of the testing track of 100 μm, line 1240 corresponds to a distance between the signal line and the parallel portion of the testing track of 0 μm (i.e., the signal line and the parallel portion are edge-aligned while being in different layers) and line 1250 corresponds to a distance between the signal line and the parallel portion of the testing track of −100 μm (i.e., the signal line and the parallel portion overlap while being in different layers).

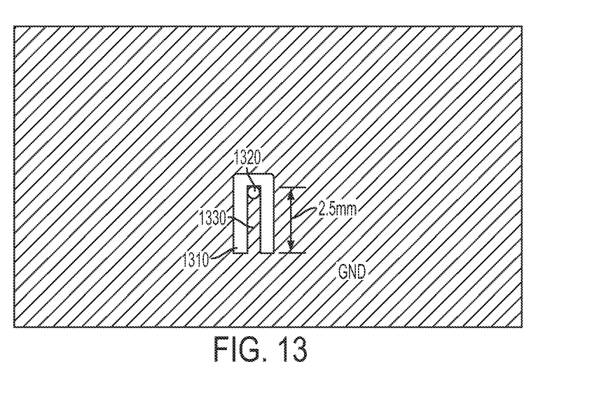

A testing track of a non-contact testing device may be formed by carving (i.e., etching) the metallic layer of a ground layer. For example, in FIG. 13, a moat 1310 of a 300 μm width is carved from a ground layer for a length of about 2.5 mm. A contact point 1320 may be formed at the end of middle portion 1330 which is the parallel portion of a non-contact testing device. Thus, the contact point 1320 is formed away from the non-carved surface of the reference layer.

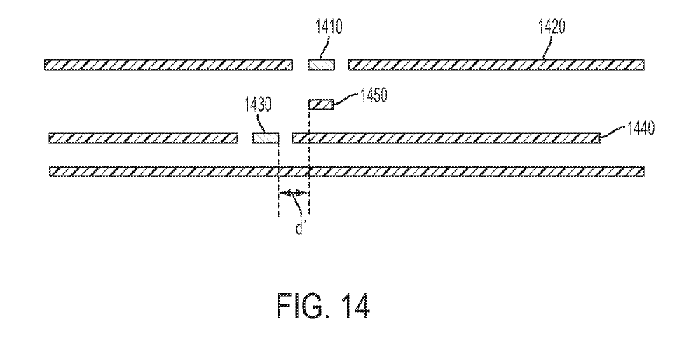

FIG. 14 illustrates a cross-section through a multi-layer PCB including exemplary embodiments of non-contact tracks formed on ground layers. Thus, a parallel portion 1410 is illustrated as being formed on a ground layer 1420 and another parallel portion 1430 is illustrated as being formed on a shadow ground layer 1440. The parallel portions 1410 and 1430 are formed to test a signal transmitted along the signal line 1450.

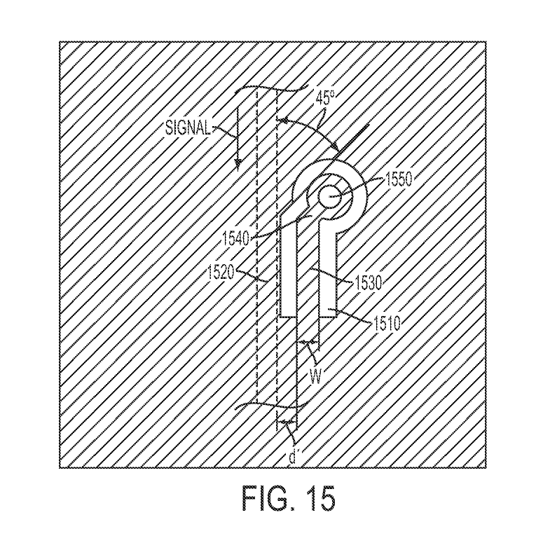

In another more complex embodiment illustrated in FIG. 15, a moat 1510 is carved at a side distance d′ of about 120 μm from a location of a signal line 1520 located on an adjacent signal layer. The width w of a parallel portion 1530 of the non-contact testing track may be about 120 μm. In a multilayer PCB, the ends of the parallel portions may not be suitable for forming a via from which the testing signal to be measured outside of the PCB. Therefore, the non-contact track may be extended to a location where the via can be formed. In FIG. 15, such an extension 1540 is illustrated for a track formed at 45° relative to the parallel portion 1530, away from the signal line 1520. The via 1550 is formed at an end of the extension 1540.

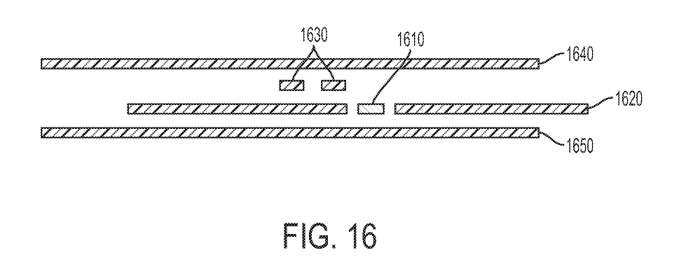

FIG. 16 illustrates another embodiment where a non-testing track 1610 is formed on an AC-ground (DC-power) reference layer 1620 to test signals transmitted via differential lines 1630 located between the reference planes 1640 and 1650.

Briefly recapitulating, non-contact testing devices can use different topologies and geometries to maximize coupling coefficient without loading the tested devices and minimize the effect on the tested signals.

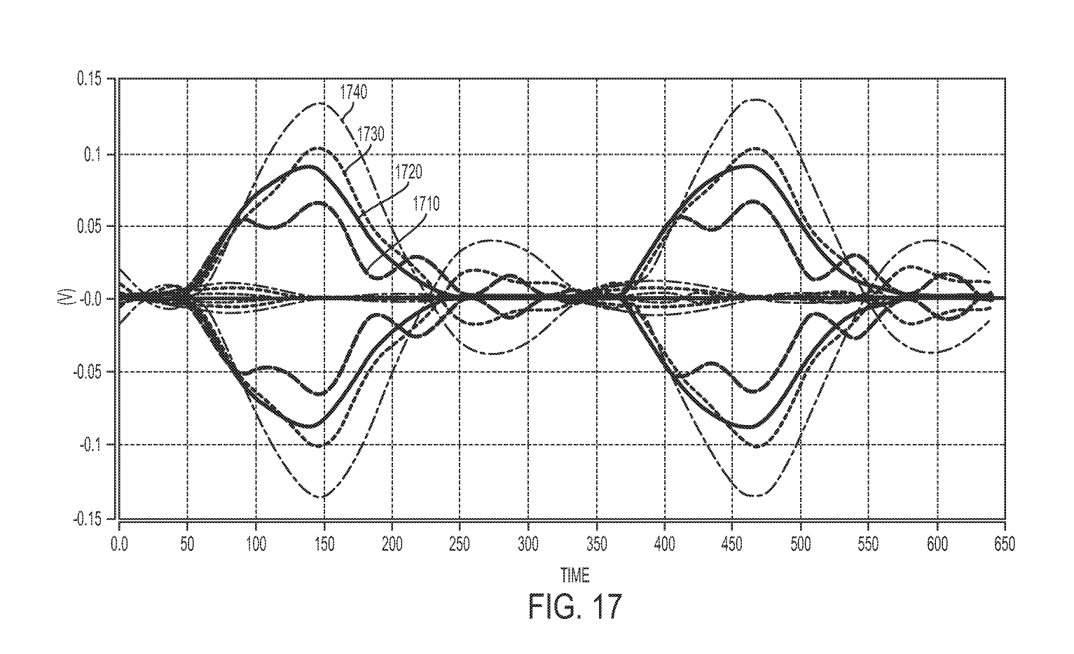

Besides, different lengths, distances to the signal lines, width location and manner of forming the non-contact testing tracks, the manner in which a non-contact testing track is terminated at an end opposite to where a contact point is located has impact relative to the shape and quality of the crosstalk signal. Thus, a non-contact testing track may have an open end, may be shorted or may be terminated via an impedance. In case there are two (differential) parallel portions as illustrated in FIG. 4, the non-contact testing tracks may be terminated in the same manner or may be terminated differently. FIG. 17 illustrates for the same length of the parallel portions (i.e., about 2.5 mm) and the same data signal rate (of 3.125 Gbps), the evolution of the crosstalk signal depending on the manners in which two (differential) non-contact testing tracks are terminated. Line 1710 corresponds to both non-contact testing tracks being open, line 1720 corresponds to both non-contact testing tracks being terminated via impedances, line 1730 corresponds to one of the non-contact testing tracks being open and the other being shorted and line 1740 corresponds to both non-contact testing tracks being shorted.

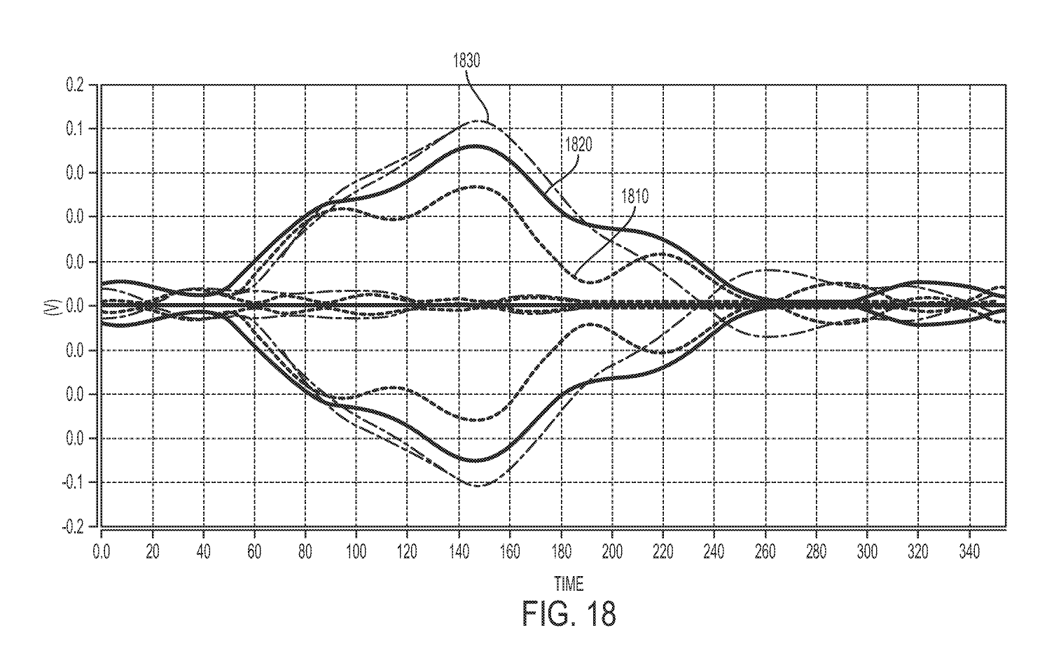

If non-contact testing tracks are shorted to the ground, crosstalk signal amplitude increases because the edge of a derivative coupled signal is boosted inductively. Forming the non-contact testing tracks by carving on reference planes has the advantage that the tracks are shorted directly to the AC ground or ground potential without the use of vias. This advantage is illustrated in FIG. 18, where line 1810 corresponds to non-contact testing tracks which are open (i.e., not terminated or shorted), line 1820 corresponds to the case in which the non-contact testing tracks are shorted to a ground potential using a via, and line 1830 corresponds to non-contact testing tracks being formed on a ground plane (i.e., shorted without a via). When the non-contact testing tracks are carved on reference planes, the return path integrity and electromagnetic boundary conditions for printed-circuit mixed-media wave-propagation are preserved using transverse induction. Non-contact testing devices using tracks shorted to ground provide proper potential for charge accumulation under tracks and less disturbance to the propagation field of the tested signal as it satisfy Gauss law for electrical charge.

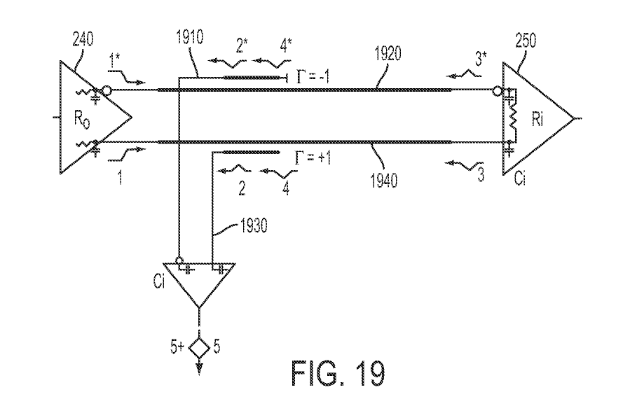

An advantage of using two non-contact testing tracks terminated differently is that the crosstalk signal integrity is enhanced by converting differential-mode noise into common-mode noise that cancels out at the differential receiver inputs. Thus, in FIG. 19, a complementary non-contact testing device has a non-contact testing track 1910 coupled to the N-leg 1920 of the signal line shorted, and a non-contact testing track 1930 coupled to the P-leg 1930 of the signal line open. Differential signals 1 and 1* propagate from the driver 240 to the receiver 250. Differential crosstalk signals 2 and 2* emerge from the parallel portions of the non-contact testing tracks. Differential-mode noise 3 and 3* reflected from the receiver 250 are converted into common-mode noise due to the short-open end connections of the non-contact testing tracks. Common-mode noise 4 and 4* cancel out at the differential inputs of the receiver 250. Differential test signals 5 and 5* emerge with improved signal quality due to cancellation of secondary reflections.

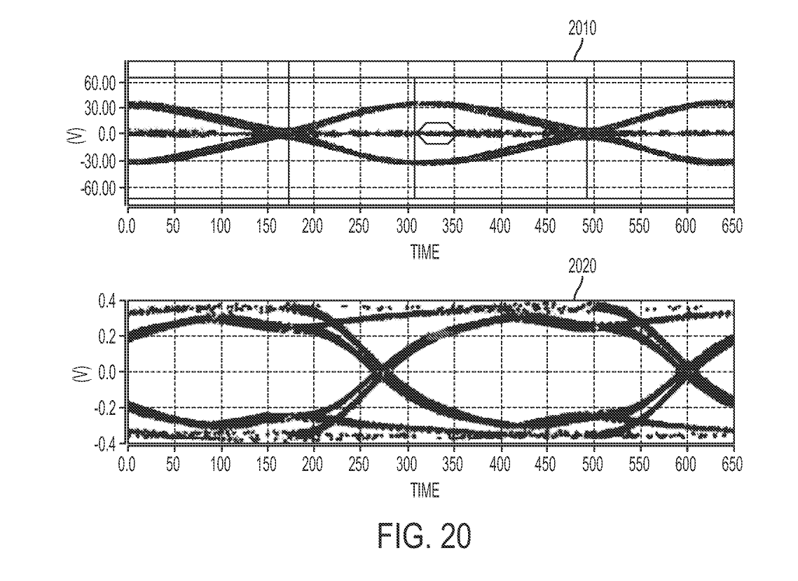

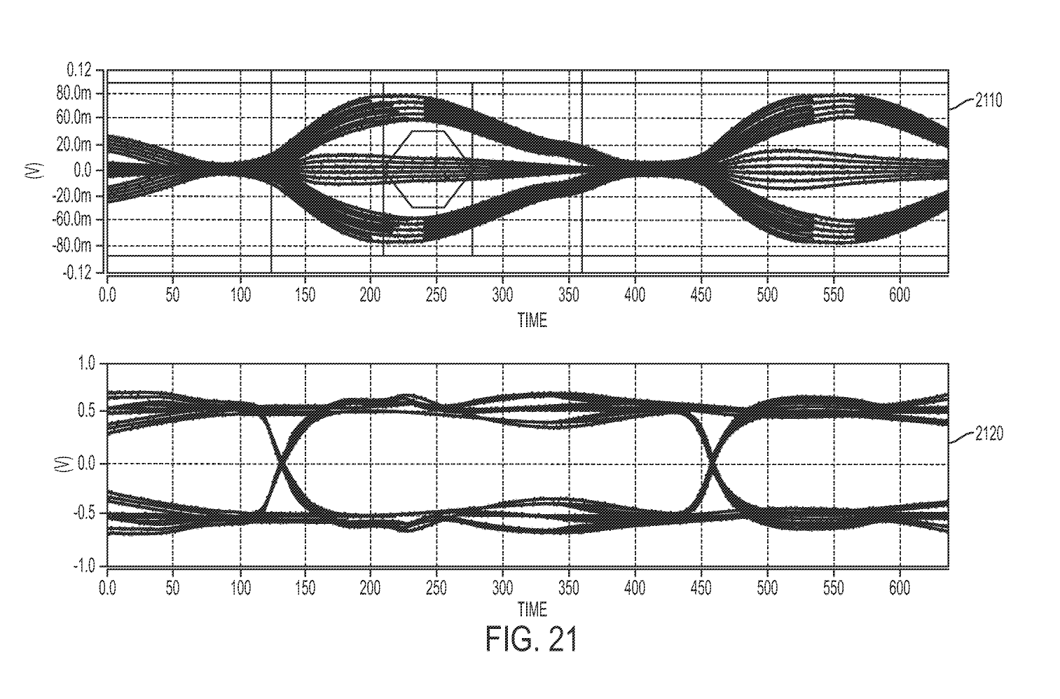

Another variation in the use of the non-contact testing devices is related to the position along a signal line where non-contact testing tracks are formed. Depending on the parameters of the tested signal that are sought to be tested, a non-contact testing device (i.e., the parallel portion of the non-contact testing track) may be located closer to the driver or closer to the receiver. FIG. 20 exemplarily illustrates simulations of a signal reaching a receiver (graph 2020) and of a corresponding crosstalk signal (graph 2010) acquired by a non-contact testing device located close to the receiver. FIG. 21 exemplarily illustrates simulations of a signal output by a driver (graph 2120) and of a corresponding crosstalk signal (graph 2110) acquired by a non-contact testing device located close to the driver.

The disclosed exemplary embodiments set forth non-contact testing devices for testing integrity of a signal transmitted on a PCB line. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

What is claimed is:

1. A method (100) of testing high-speed signals propagating along at least one signal track on a signal layer of a printed circuit board (PCB), comprising:
forming (S110) a non-contact testing track on a layer of the PCB, the non-contact testing track having at least one portion substantially parallel with the at least one signal track; and
connecting (S120) a testing point to an end of the non-contact testing track to enable measuring a crosstalk signal corresponding to the tested signal.

2. The method of claim 1, wherein a length of the at least one portion of the non-contact testing track, which portion is parallel with the at least one signal track, enables generating the crosstalk signal at a limit between a saturation crosstalk regime and a non-saturation crosstalk regime, when the tested signal has an expected data rate.

3. The method of claim 1, wherein the layer on which the non-contact testing track is formed is a different layer of the PCB than the signal layer, the different layer being adjacent to the signal layer where the at least one signal track is located.

4. The method of claim 3, wherein the different layer is another signal layer.

5. The method of claim 3, wherein the at least one portion of the non-contact testing track is formed to overlay the at least one signal track.

6. The method of claim 3, wherein the at least one portion of the non-contact testing track is formed on a side of the at least one signal track, in a projection perpendicular to the signal layer.

7. The method of claim 1, wherein the at least one portion of the non-contact testing track is formed in the signal layer where the at least one signal track is located.

8. The method of claim 1, wherein the non-contact testing track is open at an end opposite the end where the testing point is connected.

9. The method of claim 1, wherein the non-contact testing track is connected to an AC ground potential at an end opposite the end where the testing point is connected.

10. The method of claim 1, wherein the non-contact testing track is terminated via an impedance to a AC ground potential at an end opposite the end where the testing point is connected.

11. The method of claim 1, wherein the non-contact testing track is located close to a driver end of the at least one signal track.

12. The method of claim 1, wherein the non-contact testing track is located close to a receiver end of the at least one signal track.

13. The method of claim 1, wherein the at least one signal track comprises two differential signal tracks, and the non-contact testing track comprises two non-contact testing tracks located at equal electrical length from the driver relative to the two differential signal tracks.

14. The method of claim 13, wherein the two non-contact testing tracks are each open, connected to a ground potential or terminated via an impedance to a ground potential at an end opposite the end where a respective testing point is connected.

15. The method of claim 13, wherein the two non-contact testing tracks are connected to a differential amplifier.

16. The method of claim 13, wherein the two non-contact testing tracks have different reflection coefficients and are connected to a differential amplifier.

17. The method of claim 1, further comprising:
forming at least one other non-contact testing track having at least one portion substantially parallel with the at least one signal track, at another location along the at least one signal track;
measuring one other crosstalk signal corresponding to the tested signal, at another testing point connected to an end of the other non-contact testing track; and
outputting sequentially the crosstalk signal and the other crosstalk signal, to diagnose of an integrity of the testing signal along the at least one signal track.

18. The method of claim 1, further comprising:
forming a via from the testing point to a surface of the PCB.

19. The method of claim 18, wherein the non-contact testing track is formed to include another portion configured to prolong the at least one portion substantially parallel with the at least one signal track, to a location which is available for the via.

20. A method (150) of testing high-speed signals propagating along at least one signal track on a signal layer of a printed circuit board (PCB), comprising:
carving (S160) a moat on a reference layer adjacent to the signal layer to form a non-contact testing track having at least one portion substantially parallel with the at least one signal track; and
connecting (S170) a testing point to an end of the non-contact testing track away from a non-carved surface of the reference layer, to enable measuring a crosstalk signal corresponding to the tested signal.

21. The method of claim 20, wherein the reference layer is a ground layer, a power layer, or a shadow ground polygon.

22. The method of claim 20, wherein the at least one signal track comprises two differential signal tracks, and the non-contact testing track comprises two non-contact testing tracks located at equal electrical length from the driver relative to the two differential signal tracks.

23. The method of claim 20, further comprising:
forming at least one other non-contact testing track having at least one portion substantially parallel with the at least one signal track, at another location along the at least one signal track;
measuring one other crosstalk signal corresponding to the tested signal, at another testing point connected to an end of the other non-contact testing track; and
outputting sequentially the crosstalk signal and the other crosstalk signal, to diagnose of an integrity of the testing signal along the at least one signal track.

24. The method of claim 20, further comprising:
forming a via from the testing point to a surface of the PCB.

25. The method of claim 24, wherein the non-contact testing track is formed to include another portion configured to prolong the at least one portion substantially parallel with the at least one signal track, to a location which is available for the via.

26. A non-contact testing device (200) formed on a printed circuit board (PCB), to enable testing high-speed signals propagating along at least one signal track (210) located on a signal layer of the PCB, the device comprising:
a non-contact testing track (220) formed on a layer of the PCB, and having at least one portion (222) substantially parallel with the at least one signal track (210); and
a testing point (230) located at an end of the non-contact testing track (220).

27. The non-contact testing device of claim 26, wherein a length of the at least one portion of the non-contact testing track, which portion is parallel with the at least one signal track, enables generating the crosstalk signal at a limit between a saturation crosstalk regime and a non-saturation crosstalk regime, when the tested signal has an expected data rate.

28. The non-contact testing device of claim 26, wherein the layer on which the non-contact testing track is located is a different layer of the PCB than the signal layer, the different layer being adjacent to the signal layer where the at least one signal track is located.

29. The non-contact testing device of claim 28, wherein the different layer is another signal layer.

30. The non-contact testing device of claim 28, wherein the at least one portion of the non-contact testing track overlays the at least one signal track.

31. The non-contact testing device of claim 28, wherein the at least one portion of the non-contact testing track is located on a side of the at least one signal track, in a projection perpendicular to the signal layer.

32. The non-contact testing device of claim 26, wherein the at least one portion of the non-contact testing track is formed in the signal layer where the at least one signal track is located.

33. The non-contact testing device of claim 26, wherein the non-contact testing track is open at an end opposite the end where the testing point is located.

34. The non-contact testing device of claim 26, wherein the non-contact testing track is connected to an AC ground potential, at an end opposite the end where the testing point is located.

35. The non-contact testing device of claim 26, wherein the non-contact testing track is terminated via an impedance to an AC ground potential, at an end opposite the end where the testing point is located.

36. The non-contact testing device of claim 26, wherein the at least one portion of the non-contact testing track is located close to a driver end of the at least one signal track.

37. The non-contact testing device of claim 26, wherein the non-contact testing track is located close to a receiver end of the at least one signal track.

38. The non-contact testing device of claim 26, wherein the at least one single track comprises two differential signal tracks, and the non-contact testing track comprises two non-contact testing tracks located at equal electrical length from the driver relative to the two differential signal tracks.

39. The non-contact testing device of claim 38, wherein the two non-contact testing tracks are each open, connected to a ground potential or terminated via an impedance to a ground potential at an end opposite the end where a respective testing point is connected.

40. The non-contact testing device of claim 38, wherein the two non-contact testing tracks are connected to a differential amplifier.

41. The non-contact testing device of claim 38, wherein the two non-contact testing tracks have different reflection coefficients and are connected to a differential amplifier.

42. The non-contact testing device of claim 26, further comprising:
at least one other non-contact testing track having at least one portion substantially parallel with the at least one signal track, at another location along the at least one signal track;
a signal collector configured to output sequentially the crosstalk signal generated in the at least one portion of the at least one non-contact testing track and another crosstalk signal generated in the at least one portion of the at least one other non-contact testing track, to diagnose of an integrity of the testing signal along the at least one signal track.

43. The non-contact testing device of claim 26, further comprising:
a via connecting the testing point to a surface of the PCB.

44. The non-contact testing device of claim 43, wherein the non-contact testing track has another portion configured to prolong the at least one portion substantially parallel with the at least one signal track to a location which is available for the via.

45. A non-contact testing device (200) formed on a printed circuit board (PCB), to enable testing high-speed signals propagating along at least one signal track (210) located on a signal layer of the PCB, the device comprising:
a non-contact testing track (220) formed by etching a moat (1310) on a reference layer of the PCB, the reference layer (1420, 1440) being adjacent to the signal layer, and the non-contact testing track (220) having at least one portion (222) substantially parallel with the at least one signal track (210); and
a testing point (230, 1320) located at an end of the non-contact testing track (220) away from a non-carved surface of the reference layer.

46. The non-contact testing device of claim 45, wherein the reference layer is a ground layer a power layer, or a shadow ground polygon.

47. The non-contact testing device of claim 45, wherein the at least one signal track comprises two differential signal tracks, and the non-contact testing track comprises two non-contact testing tracks located at equal electrical length from the driver relative to the two differential signal tracks.

48. The non-contact testing device of claim 45, further comprising:
at least one other non-contact testing track having at least one portion substantially parallel with the at least one signal track, at another location along the at least one signal track;
a signal collector configured to output sequentially the crosstalk signal generated in the at least one portion of the at least one non-contact testing track and another crosstalk signal generated in the at least one portion of the at least one other non-contact testing track, to diagnose of an integrity of the testing signal along the at least one signal track.

49. The non-contact testing device of claim 45, further comprising:
a via connecting the testing point to a surface of the PCB.

50. The non-contact testing device of claim 48, wherein the non-contact testing track has another portion configured to prolong the at least one portion substantially parallel with the at least one signal track to a location which is available for the via.
